(19) United States
(12) Patent Application Publication
(10) Pub. No.: US 2026/0086614 A1
(43) Pub. Date: Mar. 26, 2026

(54) PEAK CURRENT DETECTION FOR SELECTING BETWEEN MEMORY POWER SUPPLY RAILS

(71) Applicant: QUALCOMM Incorporated, San Diego, CA (US)

(72) Inventors: Sreeharipriya GARIKIPATI, Hyderabad (IN); Pragya PANDE, Lucknow (IN); Rohit SINGH, Hyderabad (IN); Ankur MEHROTRA, Greater Noida (IN); Srikar KARNAM VENKAT NAGA, Bangalore (IN); Prasad Rao KOLETI, Hyderabad (IN)

(21) Appl. No.: 18/891,993

(22) Filed: Sep. 20, 2024

(51) Int. Cl. G06F 1/26; G01R 19/165

(52) U.S. Cl. CPC G06F 1/26; G01R 19/16571; G01R 19/16576

(57) ABSTRACT

Certain aspects of the present disclosure are directed towards techniques and apparatus for power control. An example apparatus generally includes a memory configured to consume power from a first voltage rail and a controller configured to: detect whether current consumption from the first voltage rail is greater than or equal to a current threshold; determine whether a voltage of a second voltage rail is greater than a voltage threshold in response to the current consumption being greater than or equal to the current threshold; and cause the memory to consume current from the second voltage rail instead of the first voltage rail based on the voltage being greater than the voltage threshold.

### TECHNICAL FIELD

Certain aspects of the present disclosure generally relate to electronic circuits and, more particularly, to techniques for supplying power.

### BACKGROUND

Power management integrated circuits (power management ICs or PMICs) are used to manage the power scheme of a host system and may include and/or control one or more voltage regulators. A PMIC may be used in battery-operated devices, such as mobile phones, tablets, laptops, wearables, etc., to control the flow and direction of electrical power in the devices. The PMIC may perform a variety of functions for the device, such as DC-to-DC conversion (e.g., using a voltage regulator as described above), battery charging, power-source selection, voltage scaling, power sequencing, etc.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for power control. The apparatus generally includes a memory configured to consume power from a first voltage rail and a controller configured to: detect whether current consumption from the first voltage rail is greater than or equal to a current threshold; determine whether a voltage of a second voltage rail is greater than a voltage threshold in response to the current consumption being greater than or equal to the current threshold; and cause the memory to consume current from the second voltage rail instead of the first voltage rail based on the voltage being greater than the voltage threshold.

Certain aspects of the present disclosure are directed towards a method for power control. The method generally includes: consuming, via a memory, power from a first voltage rail; detecting, via a controller, whether current consumption from the first voltage rail is greater than or equal to a current threshold; determining, via the controller, whether a voltage of a second voltage rail is greater than a voltage threshold in response to the current consumption being greater than or equal to the current threshold; and causing, via the controller, the memory to consume current from the second voltage rail instead of the first voltage rail based on the voltage being greater than the voltage threshold.

Certain aspects of the present disclosure are directed towards an electronic device. The electronic device generally includes a memory configured to consume power from a memory voltage rail, a central processing unit (CPU) configured to consume power from a CPU voltage rail, a cache coupled to the CPU and configured to consume power from the memory voltage rail, a controller configured to: detect whether current consumption from the memory voltage rail is greater than or equal to a current threshold; determine whether a voltage of the CPU voltage rail is greater than a voltage threshold in response to the current consumption being greater than or equal to the current threshold; and cause the cache to consume current from the CPU voltage rail instead of the memory voltage rail based on the voltage being greater than the voltage threshold.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example device that includes a power supply system, in which aspects of the present disclosure may be practiced.

FIG. 2A is a block diagram of a power multiplexer configured to shift a central processing unit (CPU) memory from a memory voltage rail to a CPU rail, in accordance with certain aspects of the present disclosure.

FIG. 2B is a flow diagram illustrating example operations for supplying power, in accordance with certain aspects of the present disclosure.

FIG. 3 is a flow diagram illustrating example operations for supplying power while forgoing component throttling, in accordance with certain aspects of the present disclosure.

FIG. 4 is a block diagram of an electronic device including power control circuitry, in accordance with certain aspects of the present disclosure.

FIG. 5 is a flow diagram illustrating example operations for power control, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards apparatus and techniques for detecting when a current consumption from a memory voltage rail is reaching a peak current consumption capability of the memory voltage rail and taking action to reduce the current consumption from the voltage rail. For example, one or more components, such as a cache for a central processing unit (CPU), may be shifted to consume power from a CPU rail instead of the memory voltage rail, reducing the current consumption from the memory voltage rail. In this manner, the number of switched-mode power supplies (SMPSs) that may be used to supply power to the memory voltage rail may be reduced, saving chipset cost and area. Moreover, by shifting the CPU memory to consume power from the CPU rail instead of the memory voltage rail, throttling of memory that are supplied power from the memory voltage rail may be avoided or at least reduced.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply or power management circuit of a communication system, a video codec, audio equipment such as music players and microphones, a television, camera equipment, and test equipment such as an oscilloscope.

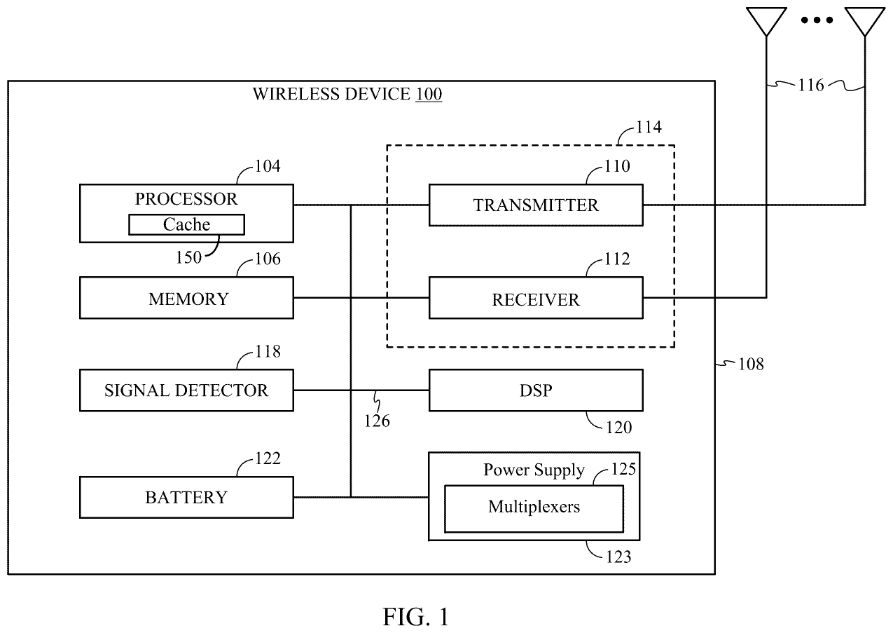

FIG. 1 illustrates an example device 100 in which aspects of the present disclosure may be implemented. The device 100 may be a battery-operated device such as a cellular phone, a personal digital assistant (PDA), a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106 provides instructions and data to the processor 104. The processor 104 typically performs logical and arithmetic operations based on program instructions stored within the memory 106. In some cases, the processor 104 may include a memory 150, such as a first level (L1) and a second level (L2) cache for the processor 104.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs). The power supply system 123 may perform a variety of functions for the device 100 such as DC-to-DC conversion, battery charging, power-source selection, voltage scaling, power sequencing, etc. For example, the power supply system 123 may include one or more power supply circuits, which may include a switched-mode power supply circuit. The switched-mode power supply circuit may be implemented by any of various suitable switched-mode power supply circuit topologies, such as a three-level buck converter, a divide-by-two (Div2) charge pump, or an adaptive combination power supply circuit, which can switch between operating in a three-level buck converter mode and a two-level buck converter mode. In some aspects, the power supply system 123 may include a power multiplexer 125 for coupling one or more electronic components to one or more voltage rails for power consumption. In some aspects, using the power multiplexer, a CPU memory such as the memory 150 may be shifted to consume power from a CPU subsystem voltage rail instead of a memory rail to reduce the current consumption from the memory rail when the total current consumption from the memory rail is reaching a peak current capability of the memory rail.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example for Power Distribution

Augmented reality (AR) and virtual reality (VR) devices, collectively known as extended reality (XR), primarily manifest as head-mounted devices (HMDs). These HMDs enable immersive experiences by overlaying digital content onto the real world or creating entirely virtual environments. The XR market is dynamic and rapidly evolving. Users and customers emphasize performance and affordability. That is, XR devices should deliver seamless visuals, low latency, and responsive interactions while being cost-effective for widespread adoption. Certain aspects of the present disclosure are directed towards techniques that facilitate the reduction of cost and area for XR devices, although the aspects of the present disclosure may be applied to any suitable electronic device.

Designing power grids for higher performance involves addressing peak current demands for each core of the device. Sufficient switched-mode power supply (SMPS) capacity is important to handle transient loads during peak demand. Increasing the number of buck converters to increase the capacity of power supply circuitry to accommodate higher peak currents increases power management integrated circuit (PMIC) costs and increases area consumption. Efficiently managing peak current may lead to an improved power grid, reducing the overall device cost (e.g., average unit cost (AuC)). That is, aligning the power grid design with peak current specifications benefits customers with cost-effective grid management.

In some implementations, a buck converter peak current may be projected and measured at the highest operating corner of a respective voltage rail. A device may have multiple voltage rails for different components, such as a central processing unit (CPU) logic voltage (CPU_v) rail for a CPU such as the processor 104, and one or more memory voltage rails for other memory (e.g., that may be external to the CPU). For example, a device may have a memory voltage (MX_v) rail and a collapsible memory voltage (MX_C_v) rail, where MX_v may be used to power (e.g., supply power to) logic for memory and MX_C_v may be used to power logic for a collapsible memory (e.g., a memory or memory cells that may be powered down to save power). The MX_v rail and MX_C_v rail may be powered via respective SMPSs, although in some cases, MX_v and MX_C_v rails may be combined into a common rail sourced from the same SMPS.

In some cases, the current consumption of each voltage rail may be computed by aggregating sensed load currents from all cores that consume power from the voltage rail. By reducing the peak current capability of a voltage rail, a single buck converter may be used for the voltage rail, or a buck converter designed with lower power may be used for the voltage rail to reduce area and cost.

Reducing peak current consumption from a memory voltage rail may help avoid throttling of memory that can negatively impact performance and aid in reducing buck converter power capability for the memory rail to reduce cost and area. Lowering the peak current consumption from the memory voltage rail opens the possibility of merging MX_v and MX_C_v rails, reducing the buck converter count. The highest contribution to the memory voltage rail peak current consumption may be from the CPU memory (e.g., a CPU subsystem (CPU_ss) memory) which may be a cache. The CPU memory may receive power from the memory voltage rail (e.g., MX_v rail). In some aspects, the CPU memory may be shifted to consume power from the CPU_v rail to reduce the peak current consumption from the memory voltage rail, allowing a reduction in the number of buck converters to save cost and area.

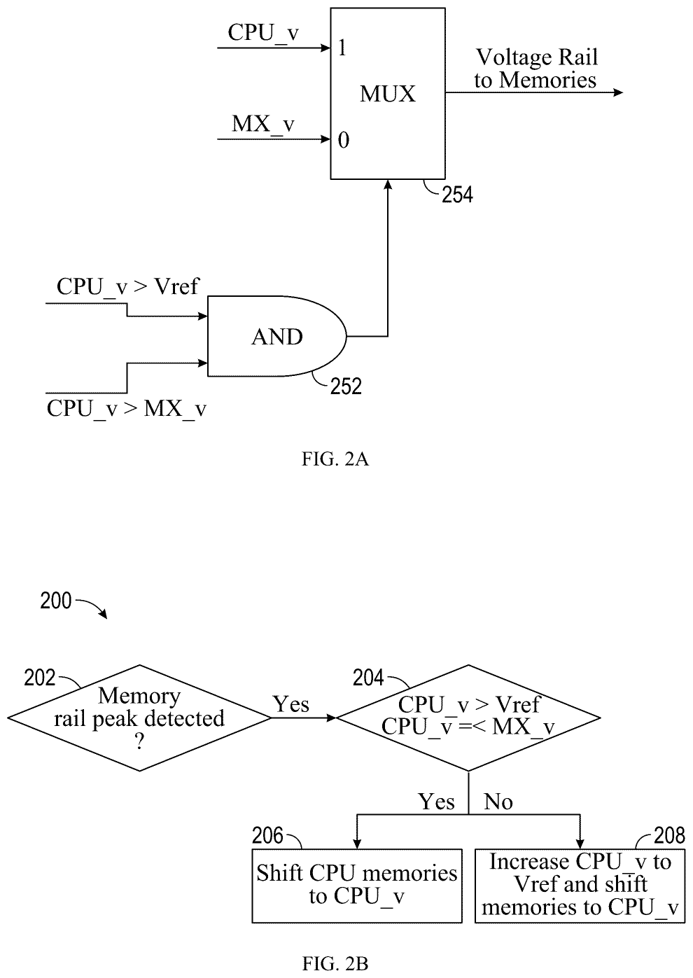

FIG. 2A is a block diagram of a power multiplexer 254 configured to shift a CPU memory from the memory voltage rail (e.g., MX_v rail) to the CPU_v rail, in accordance with certain aspects of the present disclosure. In some aspects, CPU_v may be compared with a reference voltage (Vref) to generate a first signal indicating whether CPU_v is greater than Vref, and CPU_v may be compared with the memory rail voltage (e.g., MX_v or a combined rail for MX_v and MX_C_v) to generate a second signal indicating whether CPU_v is greater than the memory rail voltage. An AND gate 252 may be used to perform an AND operation on the first and second signals. An output signal of the AND gate 252 may be provided to a control input of the power multiplexer 402. The power multiplexer 402 may receive CPU_v and the memory rail voltage (e.g., MX_v rail). Based on the output signal of the AND gate 252, the power multiplexer 402 may output either CPU_v or the memory voltage (e.g., MX_v) to power the CPU memory, as described herein. For example, if CPU_v is greater than Vref and CPU_v is greater than the memory rail voltage, the power multiplexer 404 may output CPU_v to power the CPU memory.

Vref may be a nominal voltage within a set of voltages that may be used as CPU_v. Vref may represent a voltage threshold selected to facilitate the operation of the CPU memory without the CPU memory becoming a bottleneck for CPU operations. In other words, the CPU memory may operate at a higher speed (e.g., higher frequency) with a higher rail voltage. Thus, if the CPU memory speed (e.g., read/write speed) is too low to facilitate CPU operations, the CPU memory may become a bottleneck for CPU operations degrading performance. Thus, before shifting the CPU memory to receive power from the CPU_v rail, the controller may confirm that CPU_v is greater than Vref.

As shown in FIG. 2A, the CPU memory may be shifted to consume power from CPU_v rail based on CPU_v being greater than the memory rail voltage in order to improve CPU memory operations (e.g., increase memory speed). In some aspects of the present disclosure, when the current consumption from the memory voltage rail is reaching a peak current capability of the memory voltage rail, CPU_v may be used to power the CPU memory if CPU_v is greater than Vref, regardless of whether CPU_v is greater than MX_v to reduce the peak current consumption from the memory voltage rail. In other words, even if CPU_v is less than or equal to MX_v, the CPU memory may be shifted to consume power from the CPU_v rail as long as CPU_v is greater than Vref.

FIG. 2B is a flow diagram illustrating example operations 200 for supplying power, in accordance with certain aspects of the present disclosure. The operations 200 may be performed, for example, by a controller such as the processor 104 of FIG. 1 or other logic circuitry. The controller may be a CPU co-processor in some implementations.

At block 202, the controller may detect that a current consumption from a memory voltage rail (e.g., MX_v rail or a combined rail for MX_v and MX_C_v) has reached a threshold current. For example, the threshold current may be a certain percentage (e.g., 90%) of the peak current capability of one or more SMPSs supplying power for the memory voltage rail. If so, at block 204, the controller may determine whether CPU_v is greater than Vref and whether CPU_v is less than or equal to the memory rail voltage (e.g., MX_v). If so, at block 206, the controller may shift the CPU memory to receive power from the CPU_v rail. That is, using a power multiplexer such as the power multiplexer 254, the power for the CPU memory may be provided from the CPU_v rail instead of the memory voltage rail. If not, at block 208, the controller may increase CPU_v to Vref before shifting the CPU memory to receive power from the CPU_v rail. In some implementations, increasing CPU_v may involve increasing the operating frequency of the CPU consuming power from the CPU_v rail. In other words, if the operating frequency of the CPU is increased, CPU_v may be increased to facilitate the increased operating frequency.

As described with respect to FIG. 2A, if CPU_v is greater than the memory rail voltage (e.g., MX_v), the CPU memory may already be operating from the CPU_v rail. Thus, before shifting the CPU memory to receive power from the CPU_v rail, the controller may determine, at block 204, whether CPU_v is less than or equal to MX_v (e.g., since otherwise, the CPU memory may already be operating from the CPU_v rail). Thus, if CPU_v is greater than Vref and CPU_v is less than or equal to MX_v, the controller may control the power multiplexer to shift the CPU memory to consume power from the CPU_v rail at block 206. If CPU_v is less than Vref, the controller may send an indication to the power supply system (e.g., power supply system 123 of FIG. 1) to increase CPU_v to Vref before the controller shifts the CPU memory to receive power from the CPU_v rail. In this manner, the peak current consumption from the memory rail may be reduced by shifting the CPU memory to the CPU_v rail in an effort to avoid throttling the memory and degrading the performance of cores using the memory rail.

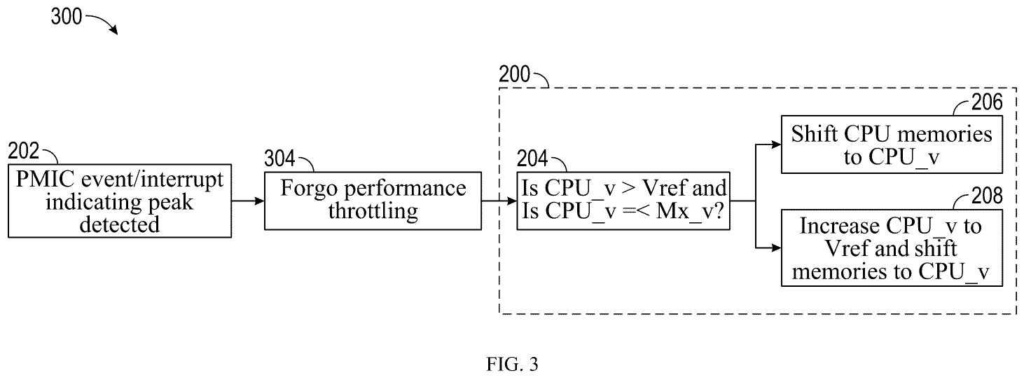

FIG. 3 is a flow diagram illustrating example operations 300 for supplying power, in accordance with certain aspects of the present disclosure. The operations 300 may be performed, for example, by a controller such as the processor 104 of FIG. 1 or other logic circuitry.

As described, at block 202, the controller may detect that the current consumption from the memory rail has reached the threshold current. The detection may be based on an occurrence of a PMIC event such as an interrupt signal from the PMIC indicating the detection of peak current consumption (e.g., the current consumption from the memory rail reaching the threshold current). Typically, the controller may begin throttling one or more cores that consume power from the memory voltage rail in response to the PMIC event. However, at block 304, the controller may forgo performing any throttling of cores to reduce the consumption of power from the memory rail. Rather, the controller may perform the operations 200 described with respect to FIG. 2B to shift the CPU memory to consume power from the CPU_v rail, as described herein.

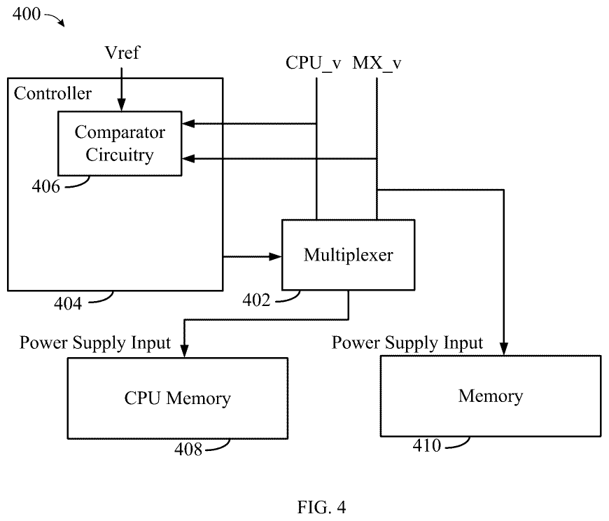

FIG. 4 is a block diagram of an electronic device 400 including power control circuitry, in accordance with certain aspects of the present disclosure. As shown, a controller 404 (e.g., corresponding to processor 104 of FIG. 1) may include comparator circuitry 406. For other aspects, the comparator circuitry 406 may be external to the controller 404. In this case, the output(s) of the comparator circuitry 406 may be input to the controller 404. The comparator circuitry 406 may receive Vref, CPU_v, and MX_v. The comparator circuitry 406 may compare CPU_v to Vref to determine whether CPU_v is greater than Vref and compare CPU_v and MX_v to determine whether CPU_v is less than or equal to MX_v. Thus, the controller 404 may determine whether CPU_v is greater than Vref and whether CPU_v is less than or equal to MX_v and control the power multiplexer 402 (e.g., corresponding to power multiplexer 254 of FIG. 2A) to either output CPU_v or MX_v to be provided to a power supply input of and power a CPU memory 408 (e.g., CPU_SS corresponding to the memory 150 of FIG. 1). As shown, MX_v may be provided to a power supply input and used to power one or more memories 410 that may be external to the CPU.

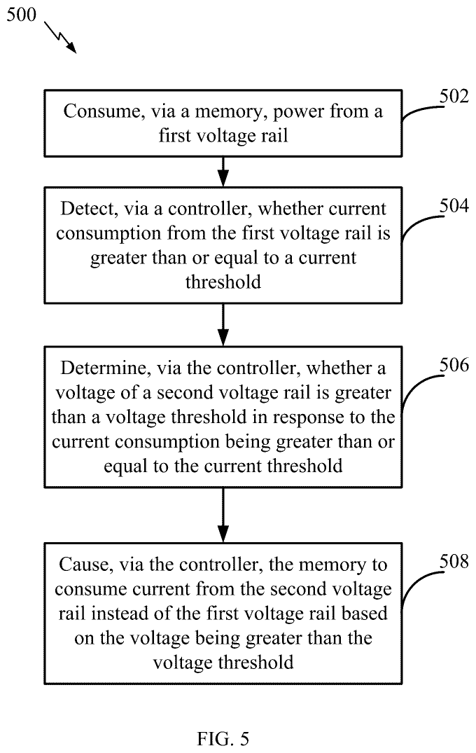

FIG. 5 is a flow diagram illustrating example operations 500 for power control, in accordance with certain aspects of the present disclosure. The operations 500 may be performed, for example, by an electronic device, such as the electronic device 400.

At block 502, the electronic device may consume, via a memory (e.g., CPU memory 408), power from a first voltage rail (e.g., memory voltage rail, such as the MX_v rail). At block 504, the electronic device may detect, via a controller (e.g., controller 404), whether current consumption from the first voltage rail is greater than or equal to a current threshold. For example, detecting whether current consumption is greater than or equal to the current threshold may include detecting whether the current consumption is at (e.g., reaching) a peak current capability associated with the first voltage rail. For example, the current consumption may be considered to be at the peak current capability if the current consumption is at 90% of the maximum current output associated with the first voltage rail.

At block 506, the electronic device may determine, via the controller, whether a voltage of a second voltage rail (e.g., CPU_v rail) is greater than a voltage threshold (e.g., Vref or a nominal voltage associated with the CPU_v rail) in response to the current consumption being greater than or equal to the current threshold. At block 508, the electronic device may cause, via the controller, the memory to consume current from the second voltage rail instead of the first voltage rail based on the voltage being greater than or equal to the voltage threshold.

In some aspects, the memory may be associated with a CPU. For example, the memory may include a CPU memory. The voltage threshold may be a voltage that allows the CPU memory to operate at a frequency that facilitates operations of a CPU. The CPU memory may be a cache for the CPU.

In some aspects, the electronic device determines whether the voltage of the second voltage rail (e.g., CPU_v rail) is less than or equal to a voltage of the first voltage rail (e.g., MX_v rail). Causing the memory to consume the current from the second voltage rail may be further based on the voltage of the second voltage rail being less than or equal to the voltage of the first voltage rail.

The electronic device may cause the voltage (e.g., CPU_v) of the second voltage rail to increase above the voltage threshold (e.g., Vref) based on the determination that the voltage of the second voltage rail is less than the voltage threshold. The memory may be caused to consume the current from the second voltage rail after the voltage of the second voltage rail has been increased above the voltage threshold.

In some aspects, the electronic device includes a multiplexer (e.g., the power multiplexer 402 of FIG. 4). The multiplexer may include a first input coupled to the first voltage rail, a second input coupled to the second voltage rail, and an output coupled to the memory. Causing the memory to consume the current from the second voltage rail may include controlling the multiplexer.

### Example Aspects

Aspect 1: An apparatus for power control, comprising: a memory configured to consume power from a first voltage rail; and a controller configured to: detect whether current consumption from the first voltage rail is greater than or equal to a current threshold; determine whether a voltage of a second voltage rail is greater than a voltage threshold in response to the current consumption being greater than or equal to the current threshold; and cause the memory to consume current from the second voltage rail instead of the first voltage rail based on the voltage being greater than the voltage threshold.

Aspect 2: The apparatus of Aspect 1, wherein the controller is configured to detect whether the current consumption is greater than or equal to the current threshold by detecting whether the current consumption is at a peak current capability associated with the first voltage rail.

Aspect 3: The apparatus of Aspect 1 or 2, wherein: the memory is associated with a CPU.

Aspect 4: The apparatus of Aspect 3, wherein the CPU memory comprises a cache for the CPU.

Aspect 5: The apparatus according to any of Aspects 1-4, wherein the controller is further configured to determine whether the voltage of the second voltage rail is less than or equal to a voltage of the first voltage rail, wherein the controller is configured to cause the memory to consume the current from the second voltage rail further based on the voltage of the second voltage rail being less than or equal to the voltage of the first voltage rail.

Aspect 6: The apparatus according to any of Aspects 1-5, wherein: the controller is further configured to cause the voltage of the second voltage rail to increase above the voltage threshold based on the determination that the voltage of the second voltage rail is less than the voltage threshold; and the controller is configured to cause the memory to consume the current from the second voltage rail after the voltage of the second voltage rail has been increased above the voltage threshold.

Aspect 7: The apparatus according to any of Aspects 1-6, further comprising a multiplexer including a first input coupled to the first voltage rail, a second input coupled to the second voltage rail, and an output coupled to a power supply input of the memory, wherein to cause the memory to consume the current from the second voltage rail, the controller is configured to control the multiplexer.

Aspect 8: The apparatus according to any of Aspects 1-7, wherein the controller is configured to cause the memory to consume current from the second voltage rail instead of throttling one or more components configured to consume power from the first voltage rail.

Aspect 9: The apparatus according to any of Aspects 1-8, wherein the memory comprises a cache for a central processing unit (CPU).

Aspect 10: The apparatus according to any of Aspects 1-9, further comprising another memory, wherein the first voltage rail is coupled to a power supply input of the other memory.

Aspect 11: A method for power control, comprising: consuming, via a memory, power from a first voltage rail; detecting, via a controller, whether current consumption from the first voltage rail is greater than or equal to a current threshold; determining, via the controller, whether a voltage of a second voltage rail is greater than a voltage threshold in response to the current consumption being greater than or equal to the current threshold; and causing, via the controller, the memory to consume current from the second voltage rail instead of the first voltage rail based on the voltage being greater than the voltage threshold.

Aspect 12: The method of Aspect 11, wherein detecting whether the current consumption is greater than or equal to the current threshold comprises detecting whether the current consumption is at a peak current capability associated with the first voltage rail.

Aspect 13: The method of Aspect 11 or 12, wherein the memory is associated with a CPU.

Aspect 14: The method of Aspect 13, wherein the CPU memory comprises a cache for the CPU.

Aspect 15: The method according to any of Aspects 11-14, further comprising determining whether the voltage of the second voltage rail is less than or equal to a voltage of the first voltage rail, wherein causing the memory to consume the current from the second voltage rail is further based on the voltage of the second voltage rail being less than or equal to the voltage of the first voltage rail.

Aspect 16: The method according to any of Aspects 11-15, wherein: the method further comprises causing the voltage of the second voltage rail to increase above the voltage threshold based on the determination that the voltage of the second voltage rail is less than the voltage threshold; and the memory is caused to consume the current from the second voltage rail after the voltage of the second voltage rail has been increased above the voltage threshold.

Aspect 17: The method according to any of Aspects 11-16, wherein: a multiplexer comprises a first input coupled to the first voltage rail, a second input coupled to the second voltage rail, and an output coupled to a power supply input of the memory; and causing the memory to consume the current from the second voltage rail includes controlling the multiplexer.

Aspect 18: The method according to any of Aspects 11-17, wherein the memory comprises a cache for a central processing unit (CPU).

Aspect 19: The method according to any of Aspects 11-18, further comprising providing power from the first voltage rail to another memory.

Aspect 20: An electronic device comprising: a memory configured to consume power from a memory voltage rail; a central processing unit (CPU) configured to consume power from a CPU voltage rail; a cache associated with the CPU and configured to consume power from the memory voltage rail; and a controller configured to: detect whether current consumption from the memory voltage rail is greater than or equal to a current threshold; determine whether a voltage of the CPU voltage rail is greater than a voltage threshold in response to the current consumption being greater than or equal to the current threshold; and cause the cache to consume current from the CPU voltage rail instead of the memory voltage rail based on the voltage being greater than the voltage threshold.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining”may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. An apparatus for power control, comprising:
a memory configured to consume power from a first voltage rail; and
a controller configured to:
detect whether current consumption from the first voltage rail is greater than or equal to a current threshold;
determine whether a voltage of a second voltage rail is greater than a voltage threshold in response to the current consumption being greater than or equal to the current threshold; and
cause the memory to consume current from the second voltage rail instead of the first voltage rail based on the voltage being greater than the voltage threshold.

2. The apparatus of claim 1, wherein the controller is configured to detect whether the current consumption is greater than or equal to the current threshold by detecting whether the current consumption is at a peak current capability associated with the first voltage rail.

3. The apparatus of claim 1, wherein:
the memory is associated with a CPU.

4. The apparatus of claim 3, wherein the CPU memory comprises a cache for the CPU.

5. The apparatus of claim 1, wherein the controller is further configured to determine whether the voltage of the second voltage rail is less than or equal to a voltage of the first voltage rail, wherein the controller is configured to cause the memory to consume the current from the second voltage rail further based on the voltage of the second voltage rail being less than or equal to the voltage of the first voltage rail.

6. The apparatus of claim 1, wherein:
the controller is further configured to cause the voltage of the second voltage rail to increase above the voltage threshold based on the determination that the voltage of the second voltage rail is less than the voltage threshold; and
the controller is configured to cause the memory to consume the current from the second voltage rail after the voltage of the second voltage rail has been increased above the voltage threshold.

7. The apparatus of claim 1, further comprising a multiplexer including a first input coupled to the first voltage rail, a second input coupled to the second voltage rail, and an output coupled to a power supply input of the memory, wherein to cause the memory to consume the current from the second voltage rail, the controller is configured to control the multiplexer.

8. The apparatus of claim 1, wherein the controller is configured to cause the memory to consume current from the second voltage rail instead of throttling one or more components configured to consume power from the first voltage rail.

9. The apparatus of claim 1, wherein the memory comprises a cache for a central processing unit (CPU).

10. The apparatus of claim 1, further comprising another memory, wherein the first voltage rail is coupled to a power supply input of the other memory.

11. A method for power control, comprising:
consuming, via a memory, power from a first voltage rail;
detecting, via a controller, whether current consumption from the first voltage rail is greater than or equal to a current threshold;
determining, via the controller, whether a voltage of a second voltage rail is greater than a voltage threshold in response to the current consumption being greater than or equal to the current threshold; and
causing, via the controller, the memory to consume current from the second voltage rail instead of the first voltage rail based on the voltage being greater than the voltage threshold.

12. The method of claim 11, wherein detecting whether the current consumption is greater than or equal to the current threshold comprises detecting whether the current consumption is at a peak current capability associated with the first voltage rail.

13. The method of claim 11, wherein the memory is associated with a CPU.

14. The method of claim 13, wherein the CPU memory comprises a cache for the CPU.

15. The method of claim 11, further comprising determining whether the voltage of the second voltage rail is less than or equal to a voltage of the first voltage rail, wherein causing the memory to consume the current from the second voltage rail is further based on the voltage of the second voltage rail being less than or equal to the voltage of the first voltage rail.

16. The method of claim 11, wherein:
the method further comprises causing the voltage of the second voltage rail to increase above the voltage threshold based on the determination that the voltage of the second voltage rail is less than the voltage threshold; and
the memory is caused to consume the current from the second voltage rail after the voltage of the second voltage rail has been increased above the voltage threshold.

17. The method of claim 11, wherein:
a multiplexer comprises a first input coupled to the first voltage rail, a second input coupled to the second voltage rail, and an output coupled to a power supply input of the memory; and
causing the memory to consume the current from the second voltage rail includes controlling the multiplexer.

18. The method of claim 11, wherein the memory comprises a cache for a central processing unit (CPU).

19. The method of claim 11, further comprising providing power from the first voltage rail to another memory.

20. An electronic device comprising:
a memory configured to consume power from a memory voltage rail;
a central processing unit (CPU) configured to consume power from a CPU voltage rail;
a cache associated with the CPU and configured to consume power from the memory voltage rail; and
a controller configured to:
detect whether current consumption from the memory voltage rail is greater than or equal to a current threshold;
determine whether a voltage of the CPU voltage rail is greater than a voltage threshold in response to the current consumption being greater than or equal to the current threshold; and
cause the cache to consume current from the CPU voltage rail instead of the memory voltage rail based on the voltage being greater than the voltage threshold.
